(19) United States
(12) Patent Application Publication
(10) Pub. No.: US 2011/0187477 A1
(43) Pub. Date: Aug. 4, 2011

(54) APPARATUS FOR FILTERING AN INPUT SIGNAL

(75) Inventor: Mark Anthony KUNES, Hitchin (GB)

(73) Assignee: Astrium Limited, Stevenage (GB)

(21) Appl. No.: 12/763,405

(22) Filed: Apr. 20, 2010

(30) Foreign Application Priority Data
Jan. 29, 2010 (EP) 10275009.8

(51) Int. Cl. H01P 1/213; H03H 7/46

(52) U.S. Cl. 333/132; 333/117; 333/167

(57) ABSTRACT

A device is disclosed for filtering an input signal, by splitting the input signal into a plurality of signals. A plurality of first and second filters are arranged to filter one of the plurality of signals. The filtered plurality of signals are combined into a filtered output signal. Each one of the plurality of signals can be filtered by one of the plurality of first filter and one of the plurality of second filters.

The present invention relates to a tunable filter, in particular to a tunable filter for space-based applications. More particularly, the present invention relates to a hybrid-coupled filter in which asymmetric bandpass filters are combined to provide a bandpass filter which is tunable in both passband width and centre frequency.

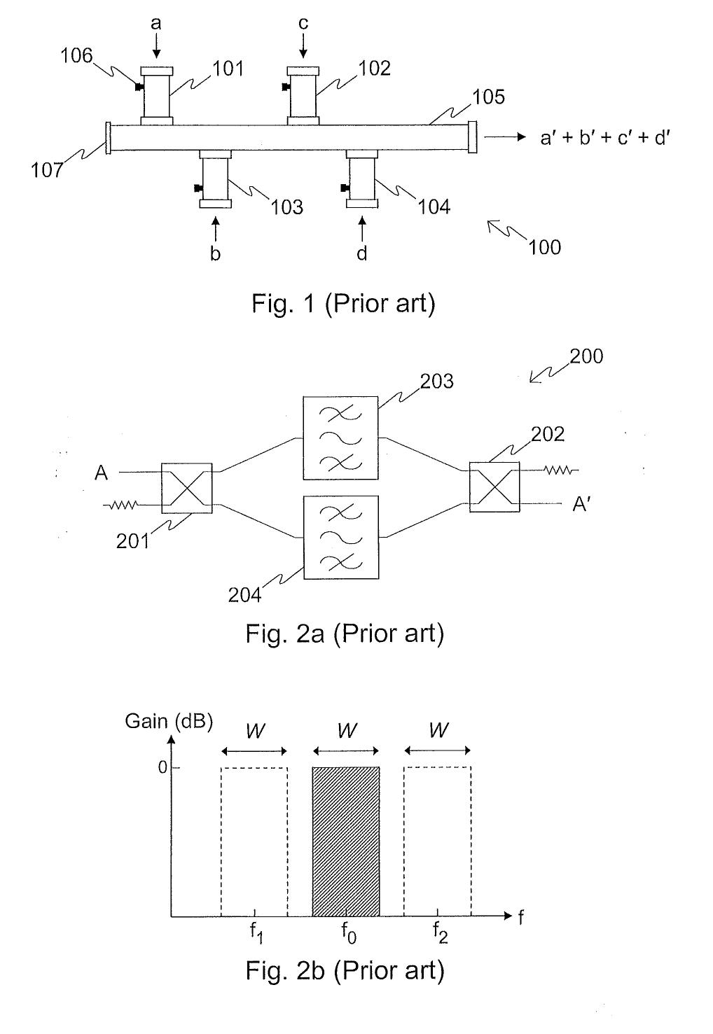

Communications satellites are commonly required to receive, process, and transmit signals across multiple communications channels. For this purpose, such satellites are typically provided with an output multiplexer (OMUX), an example of which will be briefly described with reference to FIG. 1.

The multiplexer 100 is of a type commonly referred to as a manifold multiplexer, comprising a plurality of bandpass filters 101, 102, 103, 104 disposed at varying lengths along a manifold 105. Each filter 101, 102, 103, 104 attenuates any frequencies within an input signal a, b, c, d which fall outside of the filter's passband, a centre frequency of which can be tuned by manually adjusting a tuning screw 106. The filtered signals a′, b′, c′, d′ are combined within the manifold into a frequency-multiplexed output signal a′+b′+c′+d′. However, each filter must be accurately positioned at a specific distance from the end cap 107, according to the frequency to which that filter is tuned. Therefore, the manifold multiplexer 100 cannot be retuned once the satellite is placed in orbit.

FIG. 2a illustrates a conventional hybrid-coupled filter 200. Several such filters can be cascaded in an OMUX. The hybrid-coupled filter 200 uses an input hybrid 201 to split an input signal A into two intermediate signals, each having half the power of the input signal. The intermediate signals each pass through a bandpass filter 203, 204, and are recombined into a filtered output signal A′ by an output hybrid 202. Referring to FIG. 2b, the centre frequency f₀ of each filter can be adjusted to different frequencies f₁, f₂. However, the passband width W of each bandpass filter is fixed by the filter design, and cannot be tuned once the satellite is in orbit.

The present invention aims to address the drawbacks inherent in known arrangements.

According to the present invention, there is provided an apparatus for filtering an input signal, the apparatus comprising means for splitting the input signal into a plurality of signals, a plurality of first and second filters each arranged to filter one of the plurality of signals, and means for combining the filtered plurality of signals into a filtered output signal, wherein the apparatus is arranged such that each one of the plurality of signals is filtered by one of the plurality of first filters and one of the plurality of second filters.

Each one of the first and second filters may comprise a bandpass filter having an asymmetric transfer function.

The apparatus may further comprise tuning means for adjusting a cutoff frequency of the first filters and/or a cutoff frequency of the second filters.

The tuning means may comprise a first tuning means for adjusting the cutoff frequency of the first filters, and a second tuning means for adjusting the cutoff frequency of the second filters.

Each one of the first and second filters may be arranged to operate in a TE01n transmission mode and may be formed from interconnected cylindrical cavities having moveable end plates, wherein the tuning means may comprise means for moving said end plates so as to increase or decrease an internal height of the cylindrical cavities.

The means for moving said end plates may comprise one of a stepper motor, piezoelectric actuator, or piezo walk motor.

The means for splitting the input signal may comprise at least one hybrid coupler.

The means for combining the plurality of signals may comprise at least one hybrid coupler.

The first and second filters may comprise waveguide filters arranged to filter electromagnetic radiation having a microwave wavelength.

The apparatus may comprise a filter for use in satellite-based communications.

An output multiplexer OMUX for multiplexing a plurality of input signals may comprise a plurality of hybrid-coupled filters, each arranged to receive and filter one of the plurality of input signals to produce a filtered output signal, wherein an end one of the hybrid-coupled filters is further arranged to output a multiplexed signal comprising the filtered output signals from each one of the hybrid-coupled filters.

The OMUX may further comprise control means for controlling each hybrid-coupled filter in order to separately tune at least one of a passband width and a centre frequency of the hybrid-coupled filter.

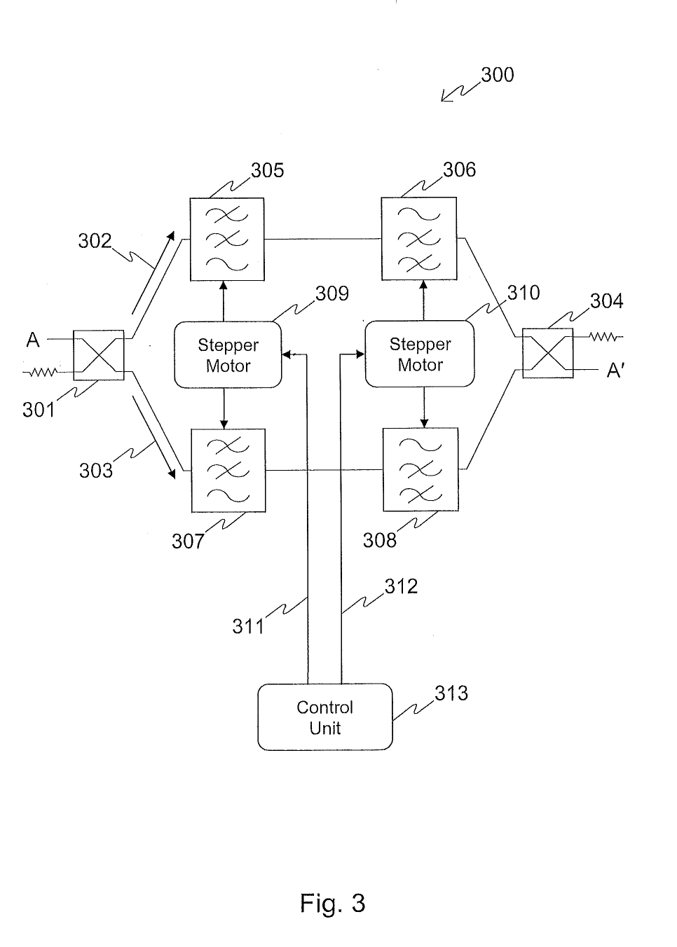

Embodiments of the present invention will now be described, by way of example, with reference to FIGS. 3 to 10 of the accompanying drawings, in which:

FIG. 1 illustrates a manifold multiplexer according to the prior art;

FIG. 2a illustrates a hybrid-coupled filter according to the prior art;

FIG. 2b illustrates a transfer function of one of the bandpass filters from the hybrid-coupled filter shown in FIG. 2a;

FIG. 3 illustrates a hybrid-coupled filter according to an example of the present invention;

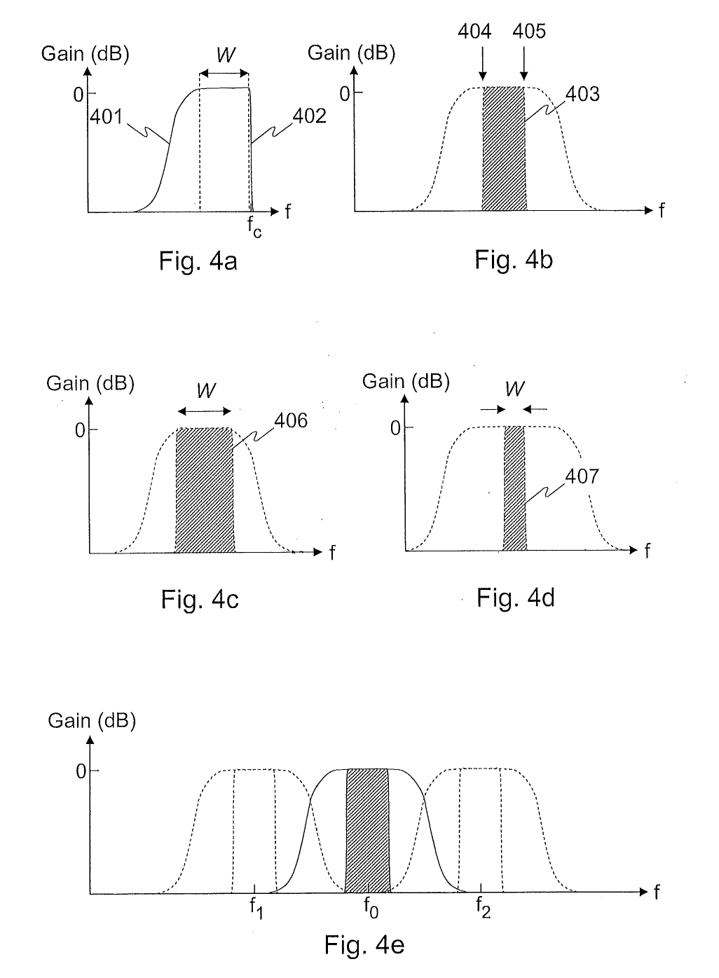

FIGS. 4a to 4e illustrate transfer functions showing how a tunable bandpass filter is formed by cascading asymmetric bandpass filters, according to an example of the present invention;

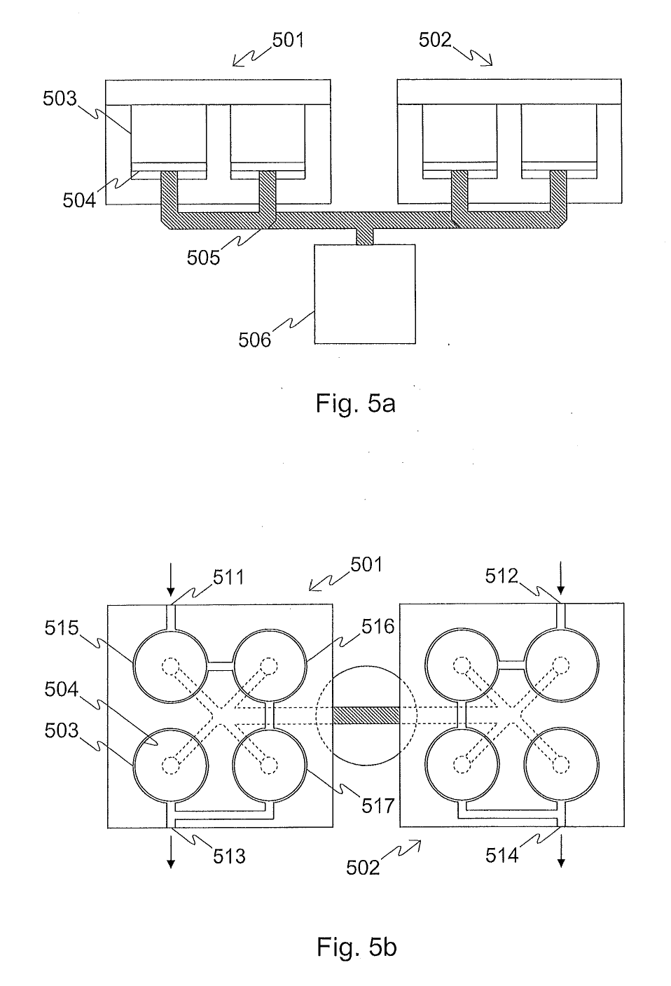

FIGS. 5a and 5b illustrate a tunable filter assembly according to an example of the present invention;

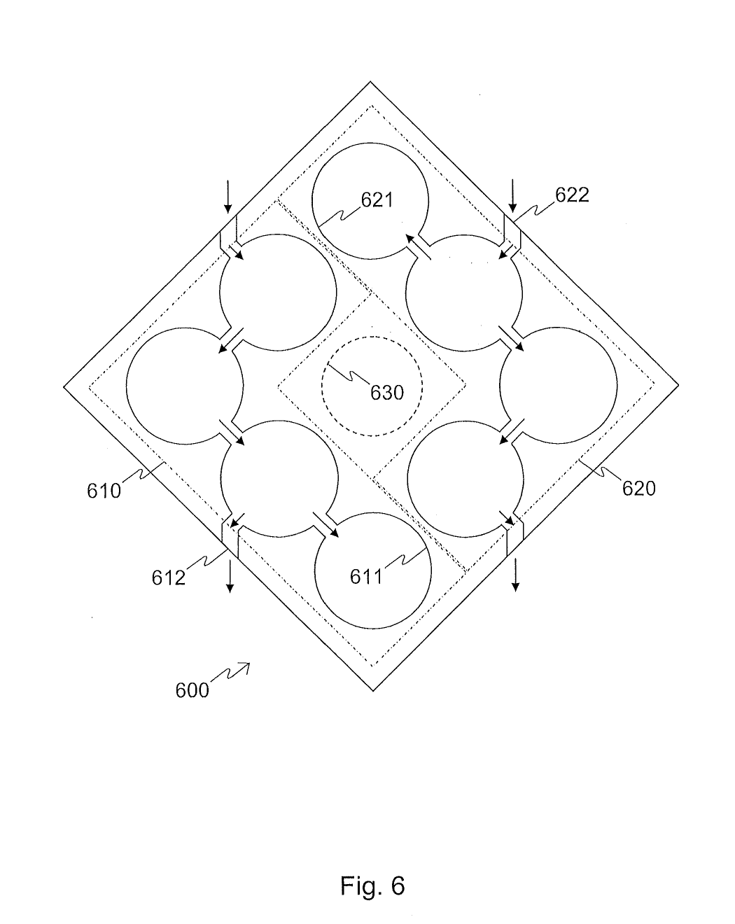

FIG. 6 illustrates a tunable filter assembly according to an example of the present invention;

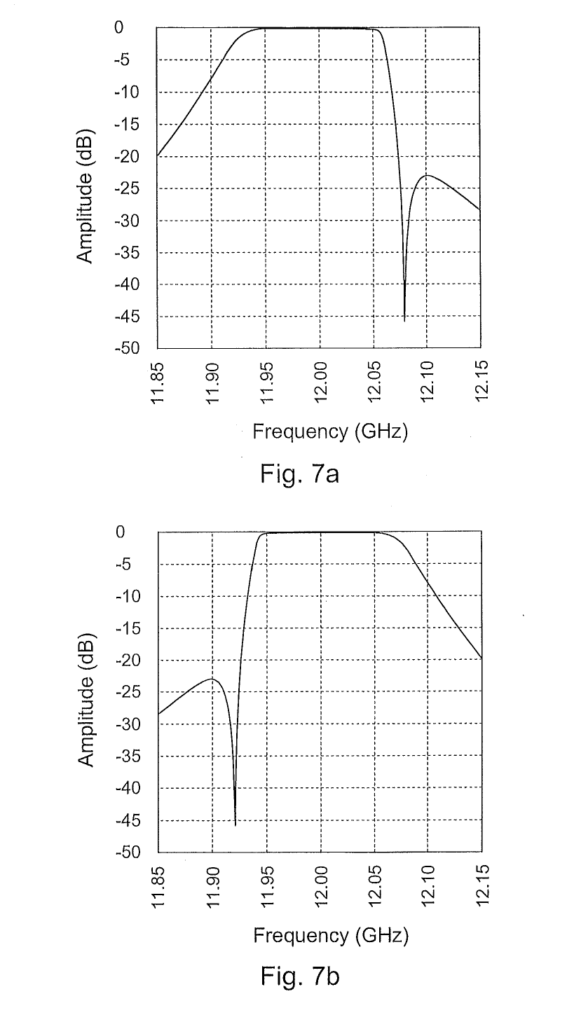

FIG. 7a illustrates a frequency response curve for the filter shown in FIG. 6 when tuned as a pseudo low-pass filter;

FIG. 7b illustrates a frequency response curve for the filter shown in FIG. 6 when tuned as a pseudo high-pass filter;

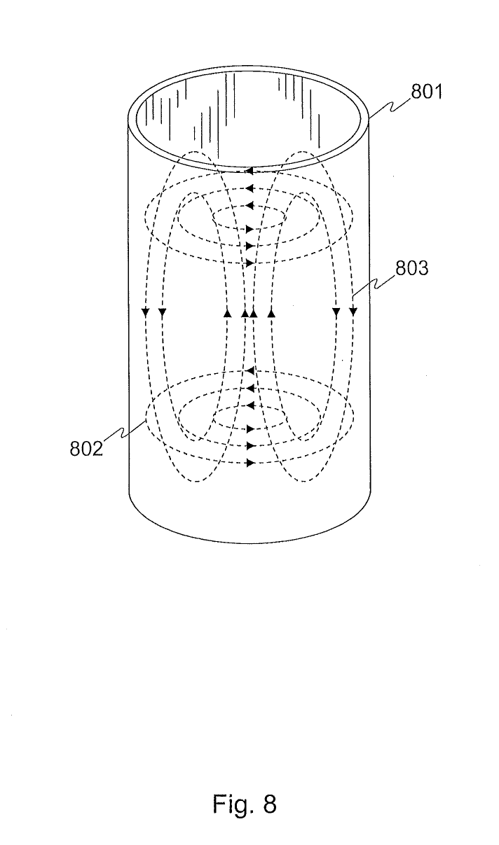

FIG. 8 illustrates electric and magnetic field patterns within a cylindrical cavity of the filter shown in FIGS. 5a and 5b;

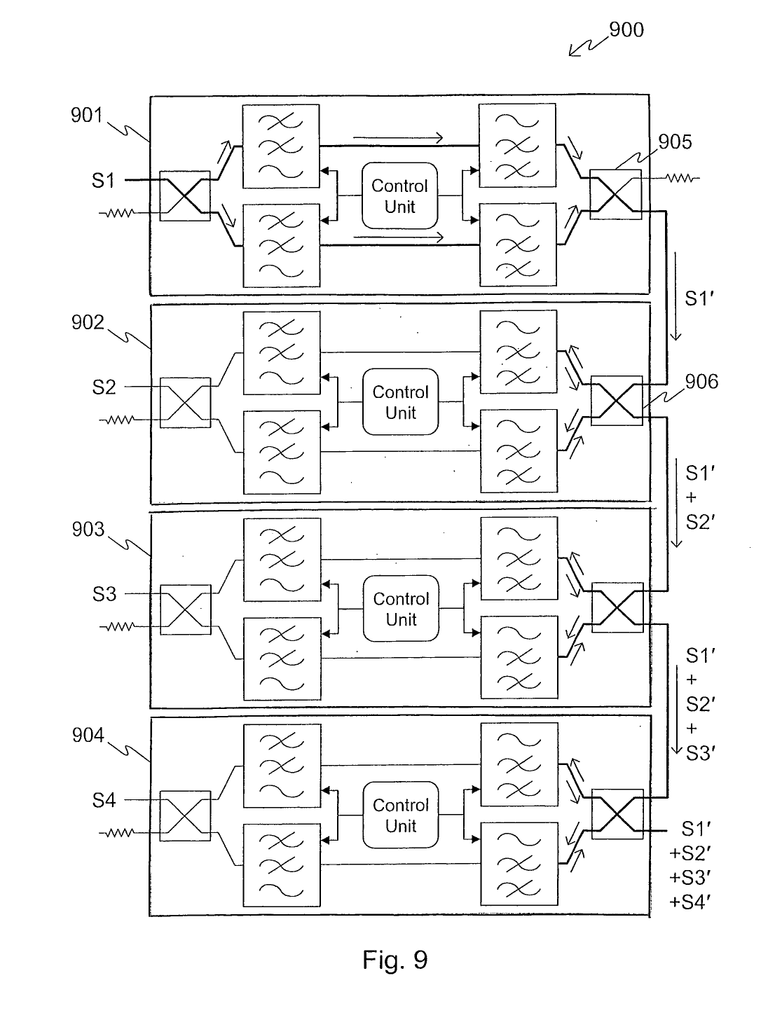

FIG. 9 illustrates a hybrid-coupled OMUX according to an example of the present invention; and

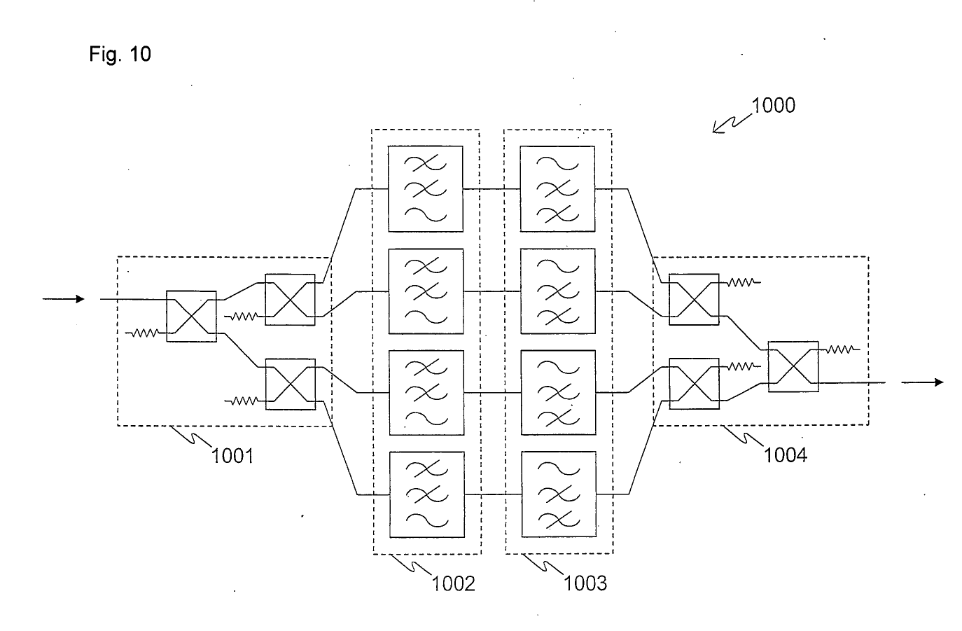

FIG. 10 illustrates a hybrid-coupled filter according to an example of the present invention.

Referring now to FIG. 3, a hybrid-coupled filter 300 is illustrated according to an example of the present invention. The hybrid-coupled filter 300 comprises an input hybrid 301 which is arranged to receive an input signal A and divide the signal equally across two signal paths 302, 303, and an output hybrid 304 which is arranged to combine signals from the two signal paths 302, 303 into a filtered output signal A′. The input and output hybrids each have a fourth port which is terminated by a matched load.

Each signal path 302 is arranged to pass through two filters 305, 306. In the present example, the filters 305, 306, 307, 308 disposed on each of the signal paths 302, 303 are asymmetric bandpass filters, which will be described later with reference to FIGS. 4a to 4e and FIGS. 5a and 5b. However, in brief, one of the filters 305 on a given signal path 302 is arranged as a pseudo low-pass filter, having a sharp roll-off on a high-frequency side of the passband and substantially attenuating all frequencies above the passband. The other filter 306 on the signal path 302 is arranged as a pseudo high-pass filter, having a sharp roll-off on a low-frequency side of the passband and substantially attenuating all frequencies below the passband. By cascading pseudo low-pass filters 305, 307 and pseudo high-pass filters 306, 308 as shown in FIG. 3, the hybrid-coupled filter 300 is able to function as a bandpass filter which is tunable in both centre frequency and bandwidth, as will be described later with reference to FIGS. 4c to 4e.

Furthermore, as the power of the input signal is divided equally across the signal paths 302, 303, low-power filters can be used to filter a high-power input signal. The hybrid-coupled filter 300 of FIG. 3 may therefore be suitable for use in a high-power OMUX, even when low-power filters are used.

Continuing with reference to FIG. 3, in the present example, both pseudo low-pass filters 305, 307 are adjusted by a first stepper motor 309, and both pseudo high-pass filters 306, 308 are adjusted by a second stepper motor 310. The first and second stepper motors 309, 310 provide a means for tuning the pseudo low-pass filters 305, 307 and pseudo high-pass filters 306, 308, as will be described later with reference to FIGS. 5a and 5b. By providing a single tuning means for simultaneously tuning all pseudo low-pass or all pseudo high-pass filters of the hybrid-coupled filter, it is possible to ensure that the filters on each signal path are tuned synchronously. However, in alternative embodiments, each filter may be provided with separate means for tuning, allowing individual filters to be fine-tuned to compensate for such factors as manufacturing defects, damage sustained during an operating lifetime of the filter, temperature variations between different filters, and so on.

The first and second stepper motors 309, 310 are controlled by a control unit 313, which is provided with separate control lines 311, 312 to enable independent tuning of the pseudo low-pass 305, 307 and pseudo high-pass 306, 308 filters. That is, the control unit 313 is able to adjust the pseudo low-pass filters 305, 307 independently of the pseudo high-pass filters 306, 308, and vice versa. Alternatively, the control unit 313 can control both stepper motors 309, 310 at the same time to simultaneously adjust both the pseudo low-pass and pseudo high-pass filters 305, 306, 307, 308. This allows the centre frequency and passband width of the hybrid-coupled filter 300 to be independently adjusted, as will be described later with reference to FIGS. 4a to 4e.

Referring now to FIGS. 4a to 4e, the cooperation of pseudo low-pass and high-pass filters to filter an input signal will be described. FIG. 4a illustrates a transfer function of one of the pseudo low-pass filters 305, 307 of FIG. 3. As described above, in the present example the pseudo low-pass filter is an asymmetric bandpass filter. The filter is arranged to have a long tail 401 on the low-frequency side of the passband, within which frequencies are partially attenuated. The high-frequency side of the passband is arranged to have a steep roll-off 402 at a cutoff frequency f_{c}. The steep roll-off 402 is provided by arranging the filter to have an extracted pole (i.e. a transmission zero) on the high-frequency side of the passband.

In contrast, a pseudo high-pass filter has a transfer function which is the mirror image of that shown in FIG. 4a. That is, a pseudo high-pass filter is arranged to have a steep roll-off on the low-frequency side of the passband and a tail on the high-frequency side of the passband. Therefore, a pseudo low-pass filter substantially attenuates all frequencies above a cutoff frequency, and a high-pass filter substantially attenuates all frequencies below a cutoff frequency. In the present example, the pseudo-low pass filter is arranged such that the width of the tail is approximately equal to the passband width W, whilst the transmission zero is occurs at a distance of approximately 0.1 W from the passband edge. However, other arrangements are possible, with the precise shape and proportions of the asymmetric passband depending on the design of the filter.

FIG. 4b illustrates how a pseudo low-pass filter and a pseudo high-pass filter combine in series to provide an overall bandpass transfer function 403 (shown by the shaded region). There is a sharp roll-off on either side of the passband, as a result of the pseudo-high pass filter having a transmission zero on the low-frequency side 404 of the passband and the pseudo-low pass filter having a transmission zero on the high-frequency side 405 of the passband. When pseudo low-pass and high-pass filters are cascaded in this way, the two filters together operate as a bandpass filter which is tunable in both passband width W and centre frequency, as shown in FIGS. 4c and 4d.

FIGS. 4c and 4d illustrate how the passband width W can be adjusted by tuning the pseudo high-pass and pseudo low-pass filters differently, relative to one another. A passband 406 of increased width W can be obtained by tuning the filters such that the cutoff frequencies of the filters move apart from one another, increasing the region of overlap. Alternatively, a passband 407 of decreased width W can be obtained by tuning the filters such that the cutoff frequencies of the filters move towards one another, decreasing the region of overlap.

Similarly, FIG. 4e illustrates how a centre frequency f₀ of the passband can be adjusted, by tuning the pseudo high-pass and pseudo low-pass filters synchronously. The centre frequency can be shifted to a lower frequency f₁ by tuning each pseudo high-pass and pseudo low-pass filter such that a cutoff frequency of each filter is decreased by the same amount. Similarly, the centre frequency can be shifted to a higher frequency f₂ by tuning each pseudo high-pass and pseudo low-pass filter such that a cutoff frequency of each filter is increased by the same amount.

FIGS. 5a and 5b illustrate a tunable filter assembly comprising two filters 501, 502, according to an example of the present invention. Although in the present example the bodies of the two filters 501, 502 are formed as separate units, in other embodiments the two filters 501, 502 may be formed as a single unit. Each one of the filters 501, 502 may be adapted to have an asymmetric transfer function corresponding to either the pseudo low-pass filters 305, 307 or the pseudo high-pass filters 306, 308 of FIG. 3. As shown in FIG. 5a, each one of the filters 501, 502 is formed from a plurality of interconnected cylindrical cavities, each cavity 503 having a moveable end plate 504. The end plates of all cylindrical cavities of both filters 501, 502 are connected to a support arm 505 (as shown by the dotted outline in FIG. 5b).

The support arm 505 is itself connected by means of a screw thread to a stepper motor 506. However, in other embodiments the stepper motor 506 may be replaced by alternative devices such as a piezo actuator or piezo walk motor. The stepper motor 506 is arranged to move the support arm 505 and end plates 504 along a direction parallel to the axes of the cylindrical cavities (i.e. the vertical direction in FIG. 5a). The end plates can therefore be finely adjusted, allowing an internal height of the cylindrical cavities to be increased or decreased in order to tune the filters to operate at different frequencies (i.e. by adjusting the cutoff frequency of each filter). Furthermore, since the end plates of both filters 501, 502 are connected to the support arm 505, this ensures that the end plates of both filters 501, 502 are moved simultaneously and by the same distance. Therefore both filters 501, 502 are synchronously tuned, i.e. tuned at the same time and to the same cutoff frequency. This ensures that the same transfer function is applied to each one of the intermediate signals produced by the input hybrid. If each intermediate signal were filtered differently, errors may be introduced into the output signal due to certain frequencies being only partially attenuated or transmitted.

Referring now to FIG. 5b, the tunable filter assembly of FIG. 5a is illustrated as viewed from above, with the cover of each filter removed. The support arm is shown by the dotted outline. Each one of the filters 501, 502 is provided with an input 511, 512 and an output 513, 514. The cylindrical cavities within each filter 501 are connected by irises, such that a signal received via the input 511 passes from one cavity to the next towards the output 512. In the present example, an asymmetric transfer function is achieved by cascading three cavities 515, 516, 517 with a fourth cavity 503 which effectively functions as a bandstop filter, providing the extracted pole.

Although in the example illustrated in FIG. 5b, the cavities are connected by irises at 90° angles, the present invention is not restricted to filters of this design. In other embodiments, the intercavity irises may be positioned at other angles, such as 135°. Such arrangements may allow a more efficient packing of the cavities, providing for a more compact filter design, and may also enable suppression of certain resonant modes.

FIG. 6 illustrates another tunable filter assembly 600 having an alternative arrangement of resonant cavities, according to an example of the present invention. The tunable filter assembly 600 comprises eight cylindrical cavities, four of which are interconnected to form a first filter 610, with the remaining four cavities being interconnected to form a second filter 620. The arrows on FIG. 6 indicate the path taken through each filter 610, 620 by a signal input to that filter 610, 620.

In the present example, the first filter 610 and second filter 620 do not have identical layouts. Specifically, the first filter 610 has an extracted pole formed from a cavity 611 close to an output 612 of the filter, whereas the second filter 620 has the extracted pole formed from a cavity 622 close to an input 622 of the filter. However, whether the extracted pole cavity is positioned at the input or output of a filter does not affect the overall transfer function of the filter, and hence both the first filter 610 and second filter 620 can be tuned to have the same frequency response curve. Furthermore, the use of 90° couplings between cavities in FIG. 6 allows suppression of the degenerate TM₀₁ mode.

The arrangement of resonant cavities within the filter assembly 600 of FIG. 6 may offer an advantage over the arrangement shown in FIG. 5b, since a stepper motor 630 can be positioned centrally amongst the cavities, as shown by the dotted outline. Since each cavity is positioned more closely to the stepper motor, a smaller support arm may be used than the one shown in FIGS. 5a and 5b, leading to a reduction in overall size and weight of the tunable filter assembly 600.

FIGS. 7a and 7b illustrate frequency response curves of filters having structures similar to that shown in FIG. 6. In the case shown in FIG. 7a, the filter is tuned as a pseudo low-pass filter, with the transmission zero on a high-frequency side of the passband (at approximately 12.08 GHz). In the case shown in FIG. 7b, the filter is tuned as a pseudo high-pass filter, with the transmission zero on a low-frequency side of the passband (at approximately 11.92 GHz). The arrangement of cavities within a pseudo low-pass filter and a pseudo high-pass filter may be the same, but with the dimensions altered as appropriate to achieve the desired frequency response.

In both FIGS. 7a and 7b, the filters are tuned to have a passband width of approximately 100 MHz. Such filters may be particularly suited for used in the Ku band, where typically bandwidths required may vary between 26-100 MHz. To achieve narrower bandwidths (e.g. closer to 26 MHz) with such pseudo low-pass and pseudo high-pass filters, the filters may be tuned to decrease the area of overlap (cf. FIGS. 4c and 4d). However, the present invention is not limited to the frequency ranges shown in FIGS. 7a and 7b, and in other embodiments the filters may be tuned to operate at different frequencies and/or have different passband widths.

Referring now to FIG. 8, an operating mode of the tunable filter assemblies of FIGS. 5a, 5b and 6 is illustrated. In the present example, each filter of the tunable filter assembly is arranged to operate in the TE₀₁₁ mode. FIG. 8 shows the electric 802 and magnetic 803 field patterns within a cylindrical cavity 801 operating in the TE₀₁₁ mode. The concentric electric field lines 802, parallel to the end plates of the cavity 801, mean that no current flows between the side faces and end plates of the cavity 801. It is therefore not essential to provide a good electrical contact between the moveable end plates and the cavity walls, and so construction of the filter may be simplified in comparison to filters operating in other modes (e.g. TE₁₁₃ mode, commonly used for filters in prior art manifold multiplexers).

Additionally, the TE₀₁₁ mode used in the present example offers a higher Q factor, and hence lower losses, in comparison to prior art filters which typically operate in the TE₁₁₃ mode. However, individual TE₀₁₁ bandpass filters are tunable only in centre frequency, and are not tunable in passband width. Also, standard low-pass and high-pass filters (i.e. “brick-wall” filters) do not employ resonator functions, and hence cannot be made to operate in the low-loss TE₀₁₁ mode and cannot easily be tuned. Therefore, in the present example, tunable asymmetric TE₀₁₁ bandpass filters are employed as pseudo low-pass and pseudo high-pass filters, which can be cascaded to provide a low-loss bandpass filter which is tunable in both passband width and centre frequency (cf. FIGS. 4b to 4e). However, the present invention is not limited to the TE₀₁₁ transmission mode, but is more generally applicable to any TE₀₁ₙ-type transmission mode.

Referring now to FIG. 9, a hybrid-coupled OMUX 700 is illustrated comprising four hybrid-coupled filters 901, 902, 903, 904, according to an example of the present invention. In FIG. 9, for clarity, the tuning means of each hybrid-coupled filter (cf. stepper motors of FIG. 3) are not shown. Although in the present example each hybrid-coupled filter is provided with a separate control unit, in other embodiments the hybrid-coupled OMUX may be provided with a single control unit for controlling some or all of the hybrid-coupled filters.

Each one of the hybrid-coupled filters 901, 902, 903, 904 receives one of four input signals S1, S2, S3, S4. The filtered output signal from each hybrid-coupled filter is sent to a port of the output hybrid of the next hybrid-coupled filter (the port which would otherwise be terminated by a fixed load in a stand-alone hybrid-coupled filter, cf. FIG. 3). When connected in this manner, the hybrid-coupled filters 901, 902, 903, 904 operate as an OMUX, with the final hybrid-coupled filter 904 outputting an output signal which contains the four filtered input signals S1′+S2′+S3′+S4′. Details of the operation of the OMUX will now be described with reference to a first one of the input signals S1.

A path taken by the first input signal S1 through the OMUX 900 is shown in bold, with the direction of propagation of the signal indicated by arrows. The first input signal S1 is input to a first one of the hybrid-coupled filters 901, which functions in a manner similar to the hybrid-coupled filter of FIG. 3, as described above. The first output hybrid 905 (i.e. the output hybrid of the first hybrid-coupled filter 901) combines the filtered intermediate signals to produce a filtered output signal S1′, which is sent to the second output hybrid 906 (i.e. the output hybrid of the second hybrid-coupled filter 902).

As hybrid couplers are linear devices, any port of the hybrid may be used as an input port. The second output hybrid 906 therefore receives the filtered output signal S1′ from the first hybrid-coupled filter 901, and splits the signal into two intermediate signals of half-power which are sent to the pseudo high-pass filters of the second hybrid-coupled filter 902. In an OMUX, to enable separation of signals after transmission, the input signals are filtered so as to occupy frequency bands which do not overlap. Therefore, the pseudo high-pass filters of the second hybrid-coupled filter 902 will be tuned so as to reject frequencies contained in the filtered output signal S1′. Hence, the intermediate filtered signals are reflected off the pseudo high-pass filters, and recombined by the second output hybrid 906 into the output filtered signal S1′.

The filtered output signal S1′ passes from one hybrid-coupled filter to the next in similar fashion, finally being output by the fourth hybrid-coupled filter 904. Second, third and fourth input signals S2, S3, S4 are respectively input to the second, third and fourth hybrid-coupled filters 902, 903, 904, filtered, passed from one hybrid-coupled filter to the next, and finally output by the fourth hybrid-coupled filter 904. Therefore, the fourth hybrid-coupled filter 904 outputs a frequency-multiplexed output signal S1′+S2′+S3′+S4′.

Although the hybrid-coupled OMUX illustrated in FIG. 9 and described above comprises four hybrid-coupled filters, the skilled person will appreciate that any number of hybrid-coupled filters may be connected as shown to form an OMUX. In general terms, an OMUX comprising a number N of hybrid-coupled filters can receive and combine N input signals into a single multiplexed output signal.

Referring now to FIG. 10, a hybrid-coupled filter 1000 is illustrated according to an example of the present invention. The hybrid-coupled filter 1000 is provided with an input hybrid network 1001 comprising three hybrids, which are arranged to split an input signal into four intermediate signals each having ¼ power compared to the input signal. Each intermediate signal passes through one of four pseudo low-pass filters 1002 and one of four pseudo high-pass filters 1003, before being recombined in an output hybrid network 1004 to produce a filtered output signal.

However, the present invention is not limited to either a single input hybrid (cf. FIG. 3) or an input hybrid network comprising three hybrids (cf. FIG. 10). In general terms, a hybrid-coupled filter may be provided with input and output networks each having 2^{N}-1 hybrids, with 2^{N} pseudo low-pass filters and 2^{N} pseudo high-pass filters (where N is an integer greater than or equal to zero). As the input signal power is divided equally amongst the intermediate signals produced by the input hybrid network, each pseudo low-pass or pseudo high-pass filter only receives a fraction of the total power of the input signal.

Therefore, although the tunable pseudo low-pass and pseudo high-pass filters may only operate at relatively low powers, by cascading the pseudo low-pass and pseudo high-pass between hybrid networks (cf. FIGS. 3 and 10), it is possible to produce a tunable high-power filter. Similarly, by cascading a plurality of such filters in an OMUX (cf. FIG. 9), a high-power OMUX is provided in which the filter on each input channel is fully tunable in both centre frequency and bandwidth. Therefore, the present invention can achieve a high degree of operational flexibility in a high-power OMUX.

Furthermore, the control unit of each filter may be remotely controlled to tune the filter, which may be particularly advantageous when the filter is to be used in space-based applications. For example, when a high-power OMUX such as the one shown in FIG. 9 is provided on a communications satellite, each filter may be remotely tuned even once the satellite is placed in orbit and is physically inaccessible.

Whilst certain embodiments of the invention have been described above, it will be clear to the skilled person that many variations and modifications are possible while still falling within the scope of the invention as defined by the claims.

For example, although in FIG. 3 an input signal A is arranged to pass through the pseudo low-pass filters 305, 307 first and the pseudo high-pass filters 306, 308 second, the order of the filters can be switched without affecting the performance of the hybrid-coupled filter 300. That is, in alternative embodiments, an input signal may be arranged to pass through the pseudo high-pass filters first and the pseudo low-pass filters second. In both cases, the overall transfer function applied to the filtered signal will be the same.

Additionally, although examples of the present invention have been described in which asymmetric bandpass filters are used, in other examples symmetric bandpass filters may be used, each filter having a transmission zero on each side of the passband. However, using asymmetric filters may provide an advantage due to the extended tail on one side of the passband effectively increasing the width of the passband, increasing the tuning range available for each hybrid-coupled filter.

Similarly, examples of the present invention have been described in which an input signal is split into a plurality of signals by means of a hybrid coupler (or plurality of hybrid couplers). However, in other examples alternative power dividers or directional couplers may be used, in which the power of the input signal is not distributed equally across the plurality of signals.

1. Apparatus for filtering an input signal, the apparatus comprising:
means for splitting the input signal into a plurality of signals;
a plurality of first and second filters each arranged to filter one of the plurality of signals; and
means for combining the filtered plurality of signals into a filtered output signal,
wherein the apparatus is arranged such that each one of the plurality of signals is filtered by one of the plurality of first filters and one of the plurality of second filters.

2. The apparatus according to claim 1, wherein each one of the first and second filters comprises a bandpass filter having an asymmetric transfer function.

3. The apparatus according to claim 1, comprising:
tuning means for adjusting a cutoff frequency of the first filters and/or a cutoff frequency of the second filters.

4. The apparatus according to claim 3, wherein the tuning means comprises:
a first tuning means for adjusting the cutoff frequency of the first filters, and a second tuning means for adjusting the cutoff frequency of the second filters.

5. The apparatus according to claim 1, wherein each one of the first and second filters is arranged to operate in a TE01n transmission mode and is formed from interconnected cylindrical cavities having moveable end plates, wherein the tuning means comprises:
means for moving said end plates so as to increase or decrease an internal height of the cylindrical cavities.

6. The apparatus according to claim 5, wherein the means for moving said end plates comprises:
one of a stepper motor, piezoelectric actuator, or piezo walk motor.

7. The apparatus according to claim 1, wherein the means for splitting the input signal comprises:
at least one hybrid coupler.

8. The apparatus according to claim 1, wherein the means for combining the plurality of signals comprises:
at least one hybrid coupler.

9. The apparatus according to claim 1, wherein the first and second filters comprise:
waveguide filters arranged to filter electromagnetic radiation having a microwave wavelength.

10. The apparatus according to claim 1, wherein the apparatus comprises:
a filter for use in satellite-based communications.

11. An output multiplexer OMUX for multiplexing a plurality of input signals, the OMUX comprising:
a plurality of hybrid-coupled filters, each comprising the apparatus according to claim 1,
wherein each one of the hybrid-coupled filters is arranged to receive and filter one of the plurality of input signals to produce a filtered output signal, and
wherein an end one of the hybrid-coupled filters is further arranged to output a multiplexed signal comprising the filtered output signals from each one of the hybrid-coupled filters.

12. The OMUX according to claim 11, comprising:
control means for controlling each hybrid-coupled filter in order to separately tune at least one of a passband width and a centre frequency of the hybrid-coupled filter.
